(19) United States
(12) Patent Application Publication
(10) Pub. No.: US 2021/0265816 A1
(43) Pub. Date: Aug. 26, 2021

(54) LASER EMITTING DEVICE

(71) Applicant: DENSO CORPORATION, Kariya-city (JP)

(72) Inventor: Fumiaki MIZUNO, Kariya-city (JP)

(21) Appl. No.: 17/179,204

(22) Filed: Feb. 18, 2021

(30) Foreign Application Priority Data
Feb. 20, 2020 (JP) 2020-026830

(51) Int. Cl. H01S 5/068; H01S 5/026

(52) U.S. Cl. CPC H01S 5/06825; H01S 5/0261

(57) ABSTRACT

A laser emitting device has a constant current source, a single charging capacitor, and one or more laser emitters. The constant current source supplies a charging current to the single charging capacitor to charge the single charging capacitor. Each of the laser emitter has a laser diode and a drive circuit. Each laser diode emits laser light in response to a power supplied from the single charging capacitor. A charging current to be supplied to the single charging capacitor is less than a threshold current of the laser diode in each of the laser emitters.

### CROSS-REFERENCE TO RELATED APPLICATION

This application is related to and claims priority from Japanese Patent Application No. 2020-026830 filed on Feb. 20, 2020, the contents of which are hereby incorporated by reference.

### TECHNICAL FIELD

The present disclosure relates to laser emitting devices.

### BACKGROUND

A laser emitting device drives a laser diode to emit laser light. For example, there is a laser emitting device having a drive circuit and laser diodes. The drive circuit drives the laser diodes to emit respective laser light.

When a short circuit failure occurs in the drive circuit, a pulse failure mode occurs, in which the laser diodes always and continuously emit laser light because of supplying an electric power of a power source of a power source to the laser diodes even if the drive circuit does not turn on the laser diodes. That is, the laser diodes continuously emit laser light in the short circuit failure. In order to avoid an occurrence of such a pulse failure mode, it is necessary for the drive circuit to have a capacitors and failure diagnosis circuits which correspond to the respective laser diodes. The capacitor supplies an electric power to the corresponding laser diodes when the drive circuit drives the laser diodes. The failure diagnosis circuit uses a charging circuit to supply an electric power to the capacitor so as to charge the capacitor. However, this technique increases the overall size of the laser emitting device when compares with that of a laser emitting device without any failure diagnosis circuit. In particular, when a laser emitting device is equipped with a plurality of the laser diodes, it is necessary to have a plurality of the failure diagnosis circuits which correspond to the respective laser diodes. Accordingly, there is a demand to provide a laser emitting device equipped with a specific circuit having a simple structure capable of appropriately responding to the pulse failure mode, in which the laser diodes always and continuously emit laser light, due to a short circuit failure.

### SUMMARY

The present disclosure provides a laser emitting device. The laser emitting device has a constant current source, a charging capacitor and one or more laser emitters. The constant current source supplies a charging current to charge the charging capacitor. Each of the laser emitter has a laser diode and a drive circuit. The drive circuit controls power supply to the charging capacitor so as to drive the corresponding laser diode. The laser diode in each of the laser emitters emits laser light in response to a power supplied from the single charging capacitor. A charging current to charge the charging capacitor is less than a threshold current of each laser diode in each of the laser emitters. Each of the laser emitter has a simple structure without any charging circuit. The laser emitting device correctly responds to a pulse failure mode, in which the laser diodes always and continuously emit laser light, due to a short circuit failure.

### BRIEF DESCRIPTION OF THE DRAWINGS

A preferred, non-limiting embodiment of the present disclosure will be described by way of example with reference to the accompanying drawings, in which:

FIG. 1 is a view showing a schematic structure of a laser emitting device according to an exemplary embodiment of the present disclosure;

FIG. 2 is a view showing a schematic structure of a laser emitting device according to a comparative example;

FIG. 3 is a timing chart showing a light emission operation of laser emitters in the laser emitting device according to the exemplary embodiment shown in FIG. 1; and

FIG. 4 is a timing chart showing a light emission operation of laser emitters in the laser emitting device according to the comparative example shown in FIG. 2.

### DETAILED DESCRIPTION OF THE PREFERRED EMBODIMENTS

Hereinafter, various embodiments of the present disclosure will be described with reference to the accompanying drawings. In the following description of the various embodiments, like reference characters or numerals designate like or equivalent component parts throughout the several diagrams.

### Exemplary Embodiment

A description will be given of a laser emitting device 10 according to an exemplary embodiment of the present disclosure.

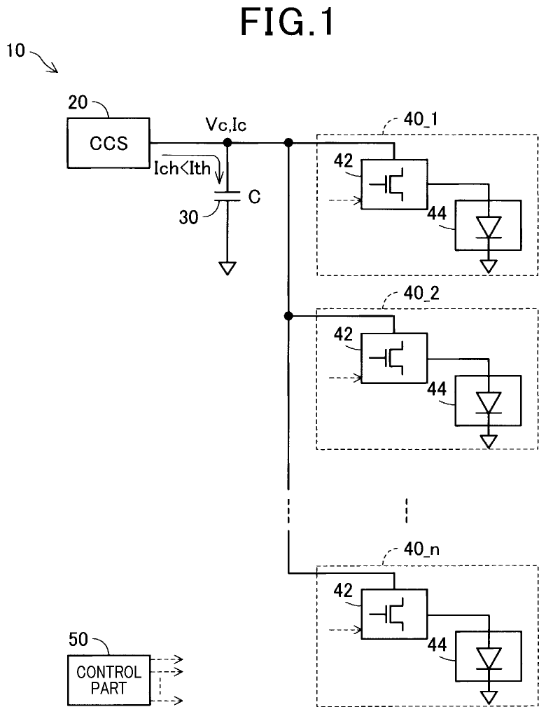

FIG. 1 is a view showing a schematic structure of the laser emitting device 10 according to the exemplary embodiment of the disclosure. As shown in FIG. 1, the laser emitting device 10 according to the exemplary embodiment has a charging capacitor 30, a plurality of laser emitters 40_1, 40_2, . . . , and 40_n (where n is a positive integer), and a control part 50. In the exemplary embodiment having an improved structure, a constant current source (CCS) 20 supplies a constant charging current Ich to the charging capacitor 30 so as to charge the charging capacitor 30 using the constant charging current Ich. The laser emitters 40_1, 40_2, . . . , and 40_n are arranged electrically in parallel with the charging capacitor 30.

It is acceptable for the laser emitting device 10 to have not less than three laser emitters. That is, the laser emitting device 10 shown in FIG. 1 has the n laser emitters 40_1, 40_2, . . . , and 40_n.

The constant current source (CCS) 20 has two functions, i.e. a constant voltage source and a constant current source. The constant current source 20 operates as a constant current source which supply the constant charging current Ich to the laser emitters 40_1, 40_2, . . . , and 40_n until a terminal voltage Vc of the charging capacitor 30 becomes not more than a constant voltage.

The function as the constant voltage source regulates this constant voltage as a threshold voltage. When the terminal voltage Vc of the charging capacitor 30 has such a constant voltage, the constant current source 20 operates as the constant voltage source when the terminal voltage Vc of the charging capacitor 30 reaches the constant voltage, and the constant charging current Ich becomes zero.

Each of the laser emitters 40_1, 40_2, . . . , and 40_n has a laser diode 44 and a drive circuit 42. The drive circuit 42 adjusts activation and inhibition of a power supply operation of the charging capacitor 30 to the laser diode 44. The drive circuit 42 drives the laser diode 44 to turn on and off the laser diode 44. As shown in FIG. 1, the drive circuit 42 is composed of a field effect transistor (FET) as an element capable of turning on and off an electric power supply operation to the corresponding laser diode 44.

In each of the laser emitters 40_1, 40_2, . . . , and 40_n in the laser emitting device 10 according to the exemplary embodiment shown in FIG. 1, an anode side of the laser diode 44 is connected to an output terminal of the drive circuit 42. However, the concept of the present disclosure does not limit this structure. It is acceptable for the anode side of the laser diode 44 to be connected to the charging capacitor 30, and for a cathode side of the laser diode 44 to be connected to the drive circuit 42.

The control part 50 is composed of a microcomputer having a central processing unit (CPU), a memory, interface ports, etc. When the CPU in the control part 50 executes programs stored in the memory so as to drive the laser emitters 40_1, 40_2, . . . , and 40_n in order. The laser diodes 44 in the laser emitters 40_1, 40_2, . . . , and 40_n emit laser light according to a driving control order by the CPU.

The light emission operation of the laser emitters 40_1, 40_2, . . . , and 40_n in the light emitting device 10 will be explained later in detail. Before the explanation of the light emission operation of the laser emitting device 10 according to the exemplary embodiment, the light emission operation of a laser emitting device 10R according to a comparative example will be explained.

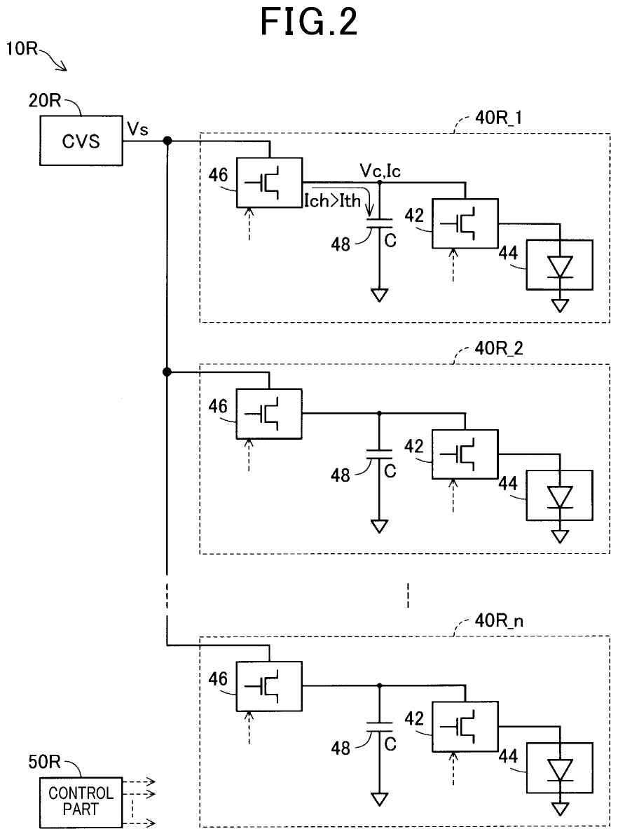

FIG. 2 is a view showing a schematic structure of the laser emitting device 10R according to the comparative example. As shown in FIG. 2, the laser emitting device 10R according to the comparative example has a constant voltage source (CVS) 20R and a plurality of laser emitters 40R_1, 40R_2, . . . , and 40R_n. The laser emitters 40R_1, 40R_2, . . . , and 40R_n are arranged electrically in parallel with the constant voltage source 20R. Similar to the structure of the laser emitting device 10 according to the exemplary embodiment shown in FIG. 1, the laser emitting device 10R according to the comparative example shown in FIG. 2 has the laser emitters 40R_1, 40R_2, . . . , and 40R_n of not less than three.

Each of the laser emitters 40R_1, 40R_2, . . . , and 40R_n has a charging capacitor 48 and a charge circuit 46 in addition to the laser diode 44 and the drive circuit 42. The charging capacitor 48 shown in FIG. 2 has the structure of the charging capacitor 30 shown in FIG. 1.

The charge circuit 46 performs the power supply operation control of a constant voltage supplied from the constant voltage source 20R so as to charge the charging capacitor 48. Similar to the drive circuit 42 shown in FIG. 1, the charge circuit 46 shown in FIG. 2 is composed of a field effect transistor (FET) as an element for turning on and off the power supply operation to the charging capacitor 48.

Similar to the control part 50 shown in FIG. 1, the control part 50R shown in FIG. 2 is composed of a microcomputer having a central processing unit (CPU), a memory, interface ports, etc. When the CPU executes programs stored in the memory so as to drive the laser emitters 40R_1, 40R_2, . . . , and 40R_n in order. The laser diodes in the laser emitters 40R_1, 40R_2, . . . , and 40R_n emit laser light in order according to the drive control of the CPU.

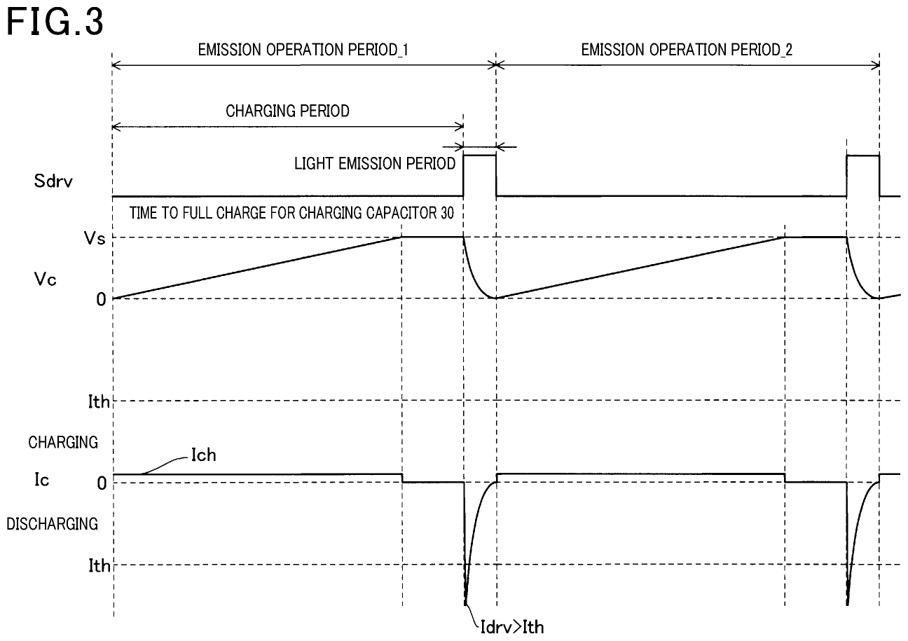

A description will now be given of the light emission operation of the laser emitting device 10 according to the exemplary embodiment shown in FIG. 1 with reference to FIG. 3, while comparing with the light emission operation of the laser emitting device 10R according to the comparative example.

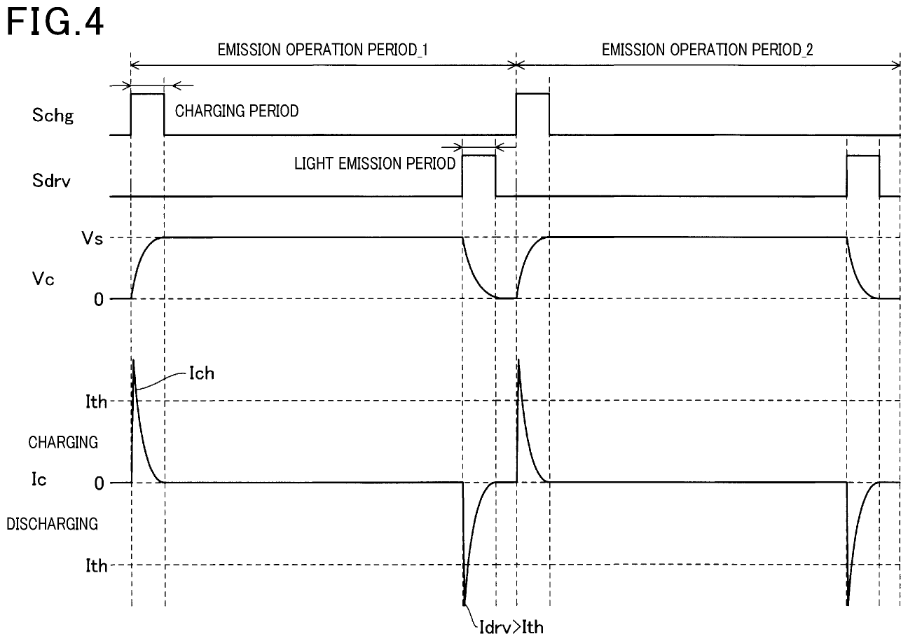

FIG. 3 is a timing chart showing the light emission operation of the laser emitters 40_1, 40_2, . . . , and 40_n in the laser emitting device 10 according to the exemplary embodiment shown in FIG. 1. FIG. 4 is a timing chart showing a light emission operation of the laser emitters 40R_1, 40R_2, . . . , and 40R_n in the laser emitting device 10R according to the comparative example shown in FIG. 2.

In an emission operation period of each of the laser emitters 40R_1, 40R_2, . . . , and 40R_n in the laser emitting device 10R according to the comparative example shown in FIG. 2, the charging capacitor 48 is charged by supplying a constant voltage Vs supplied from a constant voltage source 20R during a charging period determined by a charging signal Schg transmitted from the control part 50R to the charge circuit 46. In this charging operation, the terminal voltage Vc of the charging capacitor 48 varies to produce the constant voltage Vs according to response characteristics determined by a capacitance C of the charging capacitor 48 and an output impedance of the charge circuit 46, etc. A charging current Ich having an impulse state is generated as a terminal current Ic of the charging capacitor 48. The charging capacitor 48 is charged to have the constant voltage Vs by the charging current Ich having an impulse state during the charging period.

During the light emission period determined by the drive signal Sdrv transmitted from the control part 50R to the drive circuit 42 shown in FIG. 2, the terminal voltage Vc of the charging capacitor 48 is supplied to the laser diode 44 in each of the laser emitters 40R_1, 40R_2, . . . , and 40R_n. At this timing, the drive current Idrv having a large impulse state, which is greater than a threshold current Ith of the laser diode 44, is supplied to the laser diode 44. The laser diode 44 emits laser light. The terminal voltage Vc and the terminal current Ic of the charging capacitor 48 is gradually reduced according to the charging operation of the drive current Idrv. When the drive current Idrv becomes less than the threshold current Ith of the laser diode 44, the laser diode 44 stops emitting.

As shown in FIG. 4, the laser emitters 40R_1 emits laser light during the emission operation period_1, and the laser emitters 40R_2 emits laser light during the emission operation period_2. The emission operation period_3, . . . , and the emission operation period_n corresponding to the laser emitters 40R_3, . . . , and the laser emitters 40R_n are omitted from FIG. 4 for brevity.

In the laser emitting device 10R according to the comparative example shown in FIG. 4, repetition of charging and discharging of the charging capacitor 48 occurs during the emission operation period of each of the laser emitters 40R_1, 40R_2, . . . , and 40R_n in each of the laser emitters 40R_1, 40R_2, . . . , and 40R_n emits laser light in order.

Because each of the laser emitters 40R_1, 40R_2, . . . , and 40R_n performs the light emission by discharging electric charge accumulated in the charging capacitor 48, it is possible to avoid a pulse failure mode from occurring in each of the laser emitters 40R_1, 40R_2, . . . , and 40R_n. In this pulse failure mode, the laser diodes always and continuously emit laser light. For example, the laser diode 44 continuously emits laser light during such a pulse failure mode caused in response to a short circuit failure of the drive circuit 42 in each of the laser emitters 40R_1, 40R_2, . . . , and 40R_n. However, the light emitting device 10R according to the comparative example has the charging capacitor 48 in each of the laser emitters 40R_1, 40R_2, . . . , and 40R_n. This drawback increases the entire size of the light emitting device 10R, and a manufacturing cost thereof.

In the laser emitting device 10 according to the exemplary embodiment shown in FIG. 1, the control part 50 performs the charging control so as to charge the charging capacitor 30 during a charging period in the emission operation period of each of the laser emitters 40_1, 40_2, . . . , and 40_n. In the emission operation period of each of the laser emitters 40_1, 40_2, . . . , and 40_n, this charging period is determined on the basis of the light emission period of the laser diode 44. This light emission period is determined by the drive signal Sdrv transmitted from the control part 50 to the drive circuit 42 in each of the laser emitters 40_1, 40_2, . . . , and 40_n. That is, this drive signal Sdrv has been generated by the control part 50. The control part 50 transmits the drive signal Sdrv to the drive circuit 42 in the emission operation period of each of the laser emitters 40_1, 40_2, . . . , and 40_n shown in FIG. 3. The charging capacitor 30 is charged during the charging period in the emission operation period of each of the laser emitters 40_1, 40_2, . . . , and 40_n. In more detail, the charging period is determined by the drive signal Sdrv. As shown in FIG. 3, the charging period is counted from a start time of the emission operation period to a start time of the light emission period of each of the laser emitters 40_1, 40_2, . . . , and 40_n. As shown in FIG. 3, a time to full charge for the charging capacitor 30 in the charging period occurs before the start time of the light emission period.

Specifically, the control of the control part 50 performs the charging control so that the constant current source 20 supplies a constant current Ich as a terminal current Ic of the charging capacitor 30 so as to charge the charging capacitor 30. At this time, the terminal voltage Vc of the charging capacitor 30 is gradually increased to a predetermined voltage Vs according to the accumulation of electric charge by the constant charging current Ich. This predetermined voltage Vs is regulated by the constant voltage source of the constant current source 20 previously explained. The laser diode 44 in each of the laser emitters 40_1, 40_2, . . . , and 40_n is driven by the predetermined voltage Vs, and the laser diode 44 emits laser light on the basis of the predetermined voltage Vs.

The constant charging current Ich is determined to have a current value which is lower than the threshold current Ith of the laser diode 44 so as to prevent the laser diode 44 from being driven even if the drive circuit 42 enters in a short circuit failure.

For example, the structure of the laser emitting device 10 according to the exemplary embodiment uses the constant charging current Ich which is determined by an equation of Ich=Ith/10.

The concept of the present disclosure does not limit the magnitude of the constant charging current Ich. For example, it is acceptable to use the constant charging current Ich, which is less than the threshold current Ith, capable of adequately charging the charging capacitor 30 during the charging period counted from the start time of the emission operation period to the start time of the light emission period in the emission operation period so as to correctly drive each laser diode 44 to emit laser light.

Similar to the comparative example shown in FIG. 4, the terminal voltage Vc of the charging capacitor 30 is supplied to the laser diode 44 through the drive circuit 42 during the light emission period. When the charging capacitor 30 supplies the drive current Idrv of an impulse state, which is more than the threshold current Ith of the laser diode 44, to the laser diode 44 through the drive circuit 42, the laser diode 44 emits laser light.

In the timing chart shown in FIG. 3, the emission operation period_1 is a period in which the laser emitters 40_1 performs the light emission operation. The emission operation period_2 is a period in which the laser emitters 40_2 performs the light emission operation.

The emission operation period_3, . . . , and the emission operation period_n corresponding to the laser emitters 40_3, . . . , and the laser emitters 40_n are omitted from FIG. 3 for brevity.

In the structure of the laser emitting device 10 according to the exemplary embodiment shown in FIG. 1, as shown in FIG. 3, repetition of charging and discharging the charging capacitor 30 occurs during the emission operation period of each of the laser emitters 40_1, 40_2, . . . , and 40_n, and each of the laser emitters 40_1, 40_2, . . . , and 40_n emits laser light in order. In particular, the structure of the laser emitting device 10 according to the exemplary embodiment shown in FIG. 1 has the single charging capacitor 30.

In the structure of the laser emitting device 10 according to the exemplary embodiment shown in FIG. 1 and FIG. 3, the laser diode 44 in each of the laser emitters 40_1, 40_2, . . . , and 40_n emits laser light due to the discharging of electric charge accumulated in the single charging capacitor 30. This structure makes it possible to prevent a pulse failure mode from occurring, in which the laser diode 44 always and continuously emits laser light by the charging of the charging capacitor 30 every emission operation period of each of the laser emitters 40_1, 40_2, . . . , and 40_n. Because the charging operation of the charging capacitor 30 is performed by using the charging current Ich which is less than the predetermined threshold current Ith of the laser diode 44, even if a short circuit occurs in the drive circuit 42 and the charging current Ich is supplied to the laser diode 44, it is possible to prevent the laser diode 44 from emitting laser light.

As previously described in detail, the laser emitting device 10 according to the exemplary embodiment uses the single constant current source 20 and the single charging capacitor 30, when compared with the structure of the laser emitting device 10R according to the comparative example which requires the charging capacitor 48 and the charging circuit 46 in each of the laser emitters 40R_1, 40R_2, . . . , and 40R_n. Accordingly, the present disclosure provides the laser emitting device 10 having a simple structure capable of solving the pulse failure mode of the laser diodes 44 due to the occurrence of a short circuit failure of the drive circuit 44.

It is acceptable for the laser emitters 40_1, 40_2, . . . , and 40_n to emit laser light in a random order instead of the order from top to bottom shown in FIG. 1 so long as each of the laser emitters 40_1, 40_2, . . . , and 40_n sequentially emits laser light in a predetermined order.

### Various Modifications

A description will be given of the laser emitting device according to various modifications of the exemplary embodiment of the present disclosure.

(1) The exemplary embodiment of the present disclosure previously described has shown the laser emitting device 10 equipped with a plurality of the laser emitters 40_1, 40_2, . . . , and 40_n. However, the concept of the present disclosure does not limit this structure. It is acceptable for the laser emitting device to have a single laser emitter. This modification has a simple structure and provides a countermeasure to an occurrence of a pulse failure mode of the laser diode, in which the laser diodes always and continuously emit laser light, due to a short circuit failure of the drive circuit 42.
(2) It is possible to apply the concept of the present disclosure to various devices in addition to the laser emitting device previously described. For example, it is possible to apply the concept of the present disclosure to object detection devices equipped with a laser emitting device. Such an object detection device is a light detection and ranging (LiDAR) obtaining object information. For example, such an object detection device as a LiDAR emits laser light to objects, and receives a reflected laser light which has been reflected by the objects so as to detect the presence of objects, to detect a distance between the object detection device and an object.
(3) It is acceptable for the laser emitting device according to the present disclosure to use a dedicated computer system composed of a microcomputer, etc. Such a microcomputer has a central processing unit (CPU), a memory, interface ports, etc. When the CPU in the microcomputer executes programs stored in the memory so as to realize one or more functions and methods of the laser emitters 40_1, 40_2, . . . , and 40_n.

It is also acceptable for the laser emitting device according to the present disclosure to use a processing unit having one or more dedicated hardware logical circuits so as to realize one or more functions and methods of the laser emitters 40_1, 40_2, . . . , and 40_n.

It is also acceptable for the laser emitting device according to the present disclosure to use a combination of the microcomputer system and the dedicated hardware logical circuits previously described. In these modifications, it is acceptable to use a non-transitory computer readable storage medium for storing such programs for causing a central processing unit (CPU) in such a dedicated computer system to execute the functions and methods of the laser emitters 40_1, 40_2, . . . , and 40_n.

While specific embodiments of the present disclosure have been described in detail, it will be appreciated by those skilled in the art that various modifications and alternatives to those details could be developed in light of the overall teachings of the disclosure. Accordingly, the particular arrangements disclosed are meant to be illustrative only and not limited to the scope of the present disclosure which is to be given the full breadth of the following claims and all equivalents thereof.

What is claimed is:

1. A laser emitting device comprising:
a constant current source supplying a charging current;
a charging capacitor charged by the charging current supplied from the constant current source; and
one or more laser emitters, each comprising a laser diode and a drive circuit, the drive circuit controlling power supply to the charging capacitor to the laser diodes so as to drive the laser diodes.

2. The laser emitting device according to claim 1, wherein
the laser emitters are arranged electrically in parallel with the charging capacitor, and the laser diode in each of the laser emitters emits laser light in order.

3. The laser emitting device according to claim 1, wherein
the charging current supplied from the constant current source is less than a threshold current of the laser diode in each of the laser emitters.

4. The laser emitting device according to claim 1, further comprising a control part which generates a drive signal, and transmits the drive signal to the drive circuit in each of the laser emitters,
wherein the laser diode in each of the laser emitters emits laser light during a light emission period in an emission operation period of each of the laser emitters determined by the drive signal, and
the charging capacitor is charged by the charging current supplied from the constant current source during a charging period which is counted from a start time of the emission operation period to a start time of the light emission period of each of the laser emitters.

5. The laser emitting device according to claim 4, wherein
the control part determines a relationship between the charging current and a threshold current of the laser diode by a following equation:
Ich=Ith/10.

6. A non-transitory computer readable storage medium for storing a program for causing a central processing unit in a computer system to execute functions of the control part according to claim 4.
